(19) United States
(12) Patent Application Publication
(10) Pub. No.: US 2024/0152673 A1
(43) Pub. Date: May 9, 2024

(54) METHODS AND SYSTEMS FOR DEVELOPING MIXING PROTOCOLS

(71) Applicant: Regeneron Pharmaceuticals, Inc., Tarrytown, NY (US)

(72) Inventors: Ross KENYON, Saratoga Springs, NY (US); Saber MEAMARDOOST, Selkirk, NY (US); Thomas MADDEN, Ballston Lake, NY (US)

(73) Assignee: Regeneron Pharmaceuticals, Inc., Tarrytown, NY (US)

(21) Appl. No.: 18/503,314

(22) Filed: Nov. 7, 2023

Related U.S. Application Data
(60) Provisional application No. 63/382,684, filed on Nov. 7, 2022.

(51) Int. Cl. G06F 30/28

(52) U.S. Cl. CPC G06F 30/28

(57) ABSTRACT

A method of evaluating a mixing protocol may include identifying a domain of mixing protocol parameters for a multivariate model and identifying an evaluation criterion for the multivariate model. The method may further include using predictor screening to determine a set of mixing protocol parameters from the domain of mixing protocol parameters, wherein the set of mixing protocol parameters account for a threshold observed variance in the evaluation criterion. The method may include generating the multivariate model, wherein the multivariate model relates the set of mixing protocol parameters to the evaluation criterion. The method may also include generating an estimated value of the evaluation criterion for the mixing protocol, using the multivariate model.

### CROSS-REFERENCE TO RELATED APPLICATIONS

This application claims priority to U.S. Provisional Patent Application No. 63/382,684, filed on Nov. 7, 2022, which is hereby incorporated by reference in its entirety.

### INTRODUCTION

The present disclosure relates to systems and methods for developing and implementing mixing protocols. Some aspects of the present disclosure relate to systems and methods for high-throughput evaluation of mixing protocols related to the biological production of therapeutics.

Biopharmaceutical products (e.g., antibodies, fusion proteins, adeno-associated viruses (AAVs), proteins, tissues, cells, polypeptides, or other therapeutic products of biological origin) are increasingly being used in the treatment and prevention of infectious diseases, genetic diseases, autoimmune diseases, and other ailments. Production of the biopharmaceutical products requires precise and consistent conditions. In order to ensure that solutions including biopharmaceutical products are consistent, mixing protocols may be employed throughout the manufacturing process. The mixing protocols may assist in maintaining suitable distribution of solution components (e.g., biopharmaceutical products, cell waste, host protein, extracellular nutrients, other molecules) within the various solutions involved in the production of biopharmaceutical products.

Mixing protocols may include parameters for shape and size of a mixing vessel, direction and rate of fluid flow within the solution, and physiochemical properties of the solution. Mixing protocols may be developed for each type of biopharmaceutical product, mixing vessel geometry, media composition, and host cell. Modifications to the biopharmaceutical product, mixing vessel geometry, media composition, or host cell may require redevelopment of the mixing protocol. Conventional methods of developing a mixing protocol are time and labor intensive, and may result in an inferior mixing protocol.

### SUMMARY

Embodiments of the present disclosure may be directed to a method of a method of evaluating a mixing protocol may include identifying a domain of mixing protocol parameters for a multivariate model. The method may also include identifying an evaluation criterion for the multivariate model. In some embodiments, the method may include determining a set of mixing protocol parameters from the domain of mixing protocol parameters, using predictor screening. The set of mixing protocol parameters may account for a threshold observed variance in the evaluation criterion. The method may also include generating the multivariate model, wherein the multivariate model relates the set of mixing protocol parameters to the evaluation criterion. In some embodiments, the method may include generating an estimated value of the evaluation criterion for the mixing protocol, using the multivariate model.

In some embodiments of the present disclosure, the predictor screening is based on experimental data or data derived from a computational fluid dynamics (CFD) model. The predictor screening is based on experimental data and data derived from the CFD model, and the method may further comprise verifying the CFD model using experimental data, prior to generating the multivariate model. The threshold observed variance in the evaluation criterion may be approximately 90% of the observed variance in the evaluation criterion. The set of mixing protocol parameters may include at least three mixing protocol parameters, and/or five or less mixing protocol parameters. The set of mixing protocol parameters may include viscosity, impeller speed, fill volume, and/or impeller diameter. The evaluation criterion may be blend time. The predictor screening may include Random Forest. The method may further comprise generating a plot representing the multivariate model. The multivariate model may be an artificial neural network. The artificial neural network may be trained on data including experimental data, data derived from a computational fluid dynamics (CFD) model, or both. The artificial neural network may include a first level of nodes and a second level of nodes. The first level of nodes may include a linear activation node comprising linear relationships between one or more mixing protocol parameters of the set of mixing protocol parameters. The second level of nodes may include linear, Gaussian, and/or tangent hyperbolic relations of one or more linear combinations of one or more mixing protocol parameters of the set of mixing protocol parameters.

Further embodiments of the present disclosure may include a method of evaluating a mixing protocol. The method may include verifying a computational fluid dynamics (CFD) model using experimental data. The method may also include determining a set of mixing protocol parameters from a domain of mixing protocol parameters, using predictor screening. In some embodiments, the method includes generating an artificial neural network, wherein training data for the artificial neural network includes data generated from the CFD model. The artificial neural network may relate the set of mixing protocol parameters to an evaluation criterion. The artificial neural network may include a first level of nodes and a second level of nodes. The first level of nodes may include a linear activation node comprising linear relationships between one or more mixing protocol parameters of the set of mixing protocol parameters. The second level of nodes may include linear, Gaussian, and/or tangent hyperbolic relations of one or more linear combinations of one or more mixing protocol parameters of the set of mixing protocol parameters. The method may also include generating an estimated value of the evaluation criterion for the mixing protocol, using the artificial neural network.

In some embodiments of the present disclosure, the mixing protocol includes a protocol value for each mixing protocol parameter of the set of mixing protocol parameters, and generating the estimated value of the evaluation criterion for the mixing protocol may include generating the estimated value based on the protocol values of the mixing protocol. The set of mixing protocol parameters may include at least three mixing protocol parameters, and/or five or less mixing protocol parameters. The set of mixing protocol parameters may include viscosity, impeller speed, fill volume, and/or impeller diameter. The evaluation criterion may be blend time.

### BRIEF DESCRIPTION OF THE DRAWINGS

The accompanying drawings, which are incorporated in and constitute a part of this specification, illustrate various exemplary embodiments, and together with the description, serve to explain the principles of the disclosed embodiments. Any features of an embodiment or example described herein (e.g., composition, formulation, method, etc.) may be combined with any other embodiment or example, and all such combinations are encompassed by the present disclosure. Moreover, the described systems and methods are neither limited to any single aspect nor embodiment thereof, nor to any combinations or permutations of such aspects and embodiments. For the sake of brevity, certain permutations and combinations are not discussed and/or illustrated separately herein.

FIG. 1 depicts in flow-chart form, an exemplary method for evaluating mixing protocols, according to aspects of the present disclosure;

FIG. 2 depicts, in flow-chart form, an exemplary method for developing a computational fluid dynamic (CFD) model, according to aspects of the present disclosure;

FIG. 3 is a flow field generated from CFD calculations and including an average velocity, according to aspects of the present disclosure;

FIG. 4 is a species mixing plot, according to aspects of the present disclosure;

FIG. 5 is a graphical representation of refining mesh resolution, according to aspects of the present disclosure;

FIG. 6 is a plot comparing CFD calculations based on different tracer injection locations;

FIG. 7 depicts a plot of blend time determined by CFD analysis versus experimentally determined blend times, according to aspects of the present disclosure;

FIG. 8 depicts a plot of residuals of CFD determined blend times, according to aspects of the present disclosure;

FIG. 9 depicts a plot of standard errors of CFD determined blend times, according to aspects of the present disclosure;

FIG. 10 depicts a plot showing results of an exemplary predictor screening of mixing protocol parameters, according to aspects of the present disclosure;

FIG. 11 depicts a plot comparing coefficients of determination of types of multivariate models, according to aspects of the present disclosure;

FIG. 12 is a diagram of an exemplary artificial neural network relating an evaluation criterion to a set of mixing protocol parameters, according to aspects of the present disclosure;

FIG. 13 depicts a plot of blend time determined by CFD analysis versus blend times predicted by a multivariate model, according to aspects of the present disclosure;

FIG. 14 depicts a plot of blend time determined by CFD analysis versus blend times predicted by a multivariate model, according to aspects of the present disclosure;

FIGS. 15, 16, 17, and 18 include plots of a relationship between blend time and viscosity, impeller speed, fill volume, and impeller diameter, according to aspects of the present disclosure.

### DETAILED DESCRIPTION

Unless defined otherwise, all technical and scientific terms used herein have the same meaning as is commonly understood by one of ordinary skill in the art to which this disclosure belongs. Although any suitable methods and materials (e.g., similar or equivalent to those described herein) can be used in the practice or testing of the present disclosure, particular example methods are now described. All publications mentioned are hereby incorporated by reference.

As used herein, the terms “comprises,” “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. The term “exemplary” is used in the sense of “example,” rather than “ideal.” For the terms “for example” and “such as,” and grammatical equivalences thereof, the phrase “and without limitation” is understood to follow unless explicitly stated otherwise.

The terms “culture medium” or “medium” refer to a nutrient solution used for growing cells that typically provides the necessary nutrients to enhance growth of the cells, such as a carbohydrate energy source, essential amino acids, trace elements, vitamins, etc. Culture media may contain extracts, e.g., serum or peptones (hydrolysates), which supply raw materials that support cell growth. In some embodiments, instead of animal-derived extracts, media may contain yeast-derived or soy extracts. Chemically defined medium refers to a culture medium in which all of the chemical components are known. Chemically defined medium may be entirely free of animal-derived components, such as serum- or animal-derived peptones. Medium may also be protein-free. “Fresh media” may refer to media that has not yet been introduced into cell culture and/or has not yet been utilized by cells of a cell culture. Fresh media may include generally high nutrient levels and little-to-no waste products. “Spent media” may refer to media that has been used by cells in cell culture, and may generally include lower nutrient levels and higher water levels, compared to fresh media.

Generally, mixing protocols may be incorporated into several stages of the manufacture of biopharmaceutical products. For example, during the culture of host cells or the harvest of a biopharmaceutical product, a mixing protocol may be utilized to ensure suitable distribution of generated biopharmaceutical products, cells, nutrients, waste, and other components of the culture media. The mixing protocol may be employed with a vessel configured to execute a mixing protocol, also referred to as a mixing vessel. In some embodiments, a bioreactor may be used as the mixing vessel. In other embodiments, culture fluid may be transferred from a bioreactor to a different type of mixing vessel prior to execution of a mixing protocol.

After the harvest of a biopharmaceutical product (e.g., a protein of interest), the harvested product may be kept in solution. The solution including the biopharmaceutical product may undergo one or more chromatography, filtration (e.g., ultrafiltration, diafiltration, or a combination thereof), purification (e.g., viral inactivation) steps to increase the purity and effectiveness of the biopharmaceutical product. At all stages, a mixing protocol may be employed to homogenize the solution and/or ensure suitable distribution of solution components. In addition to the applications discussed above, mixing protocols may be employed to combine and/or dilute individual biotainers, batches, or lots.

Additionally, mixing protocols may be applied to solutions not including the protein of interest. For example, the aforementioned steps of biopharmaceutical product manufacture require the use of buffers, media, and other solutions. The preparation of buffers, media, and other solutions may include the use of one or more mixing protocols.

Specific properties of biopharmaceutical products or the manufacturing process thereof that are dependent on the mixing protocol may be monitored to assess the impact of parameters of the mixing protocol on the resulting biopharmaceutical products. For example, the flow pattern, fluid velocity distribution, fluid flow vector field, fluid flow streamlines, unmixed volume percentage, mixing index, blend time (e.g., steady state blend time or transient blend time), residence time distribution, contour shear strain rate, average shear strain rate, exposure analysis, and/or power consumption associated with a mixing protocol may be used to assess the utility and/or efficacy of a mixing protocol.

As described herein, mixing protocols may be developed that ensure vortexing or foaming does not occur during the mixing protocol. The avoidance of vortexing and/or foaming prevents air entrainment, and other events which may negatively affect the quality of the biopharmaceutical product. Generally, mixing protocols may be developed that minimize blend time and/or power consumption without negatively affecting the quality of the biopharmaceutical product.

A mixing protocol may include operation parameters for a mixing vessel such as, for example, size of mixing vessel, impeller speed, load size as a percentage of total capacity, viscosity of solution, and/or other operation parameters that describe the requirements of the mixing protocol. In some embodiments, a mixing protocol is complete when the solution (including, e.g., media, cells, protein(s) of interest, and/or other molecules) is sufficiently homogenized. The duration of a mixing protocol, i.e., the time it takes for the solution to reach sufficient homogeneity, is referred to as the blend time. The extent to which a solution has been mixed may be quantified by a mixing index. The mixing index may be defined as the ratio of the standard deviation of concentration (e.g., of a protein of interest or other molecule) to a final concentration. Blend time may be quantified as the amount of time necessary under a given mixing protocol to reach a mixing index of approximately less than or equal to 5% (e.g., approximately 1%).

Systems and methods disclosed herein may provide an improved development flow for mixing protocols. For example, the systems and methods described herein may allow for the development of predictive models that enable the high-throughput evaluation of mixing protocols. Predictive models may be generated that can quantify evaluation criteria associated with a mixing protocol. Evaluation criteria may include “output variables” or aspects of the mixing protocol that depend on the values chosen for mixing protocol parameters. Examples of evaluation criteria include, but are not limited to, flow pattern, fluid velocity distribution, fluid flow vector field, fluid flow streamlines, other flow or turbulence statistics, unmixed volume percentage, mixing index, blend time (e.g., steady state blend time or transient blend time), residence time distribution, species mixing, free-surface behavior contour shear strain rate, average shear strain rate, exposure analysis, power consumption, pressure, turbulent dissipation rate, and Kolmogorov length.

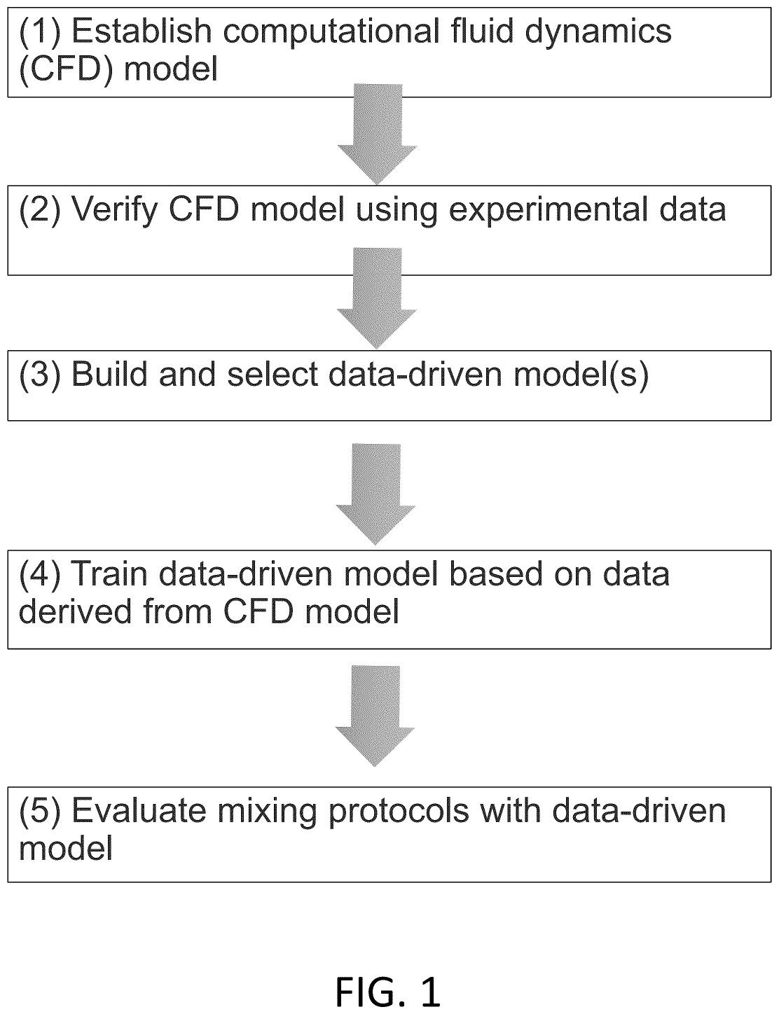

Referring to FIG. 1, a flow chart describes an exemplary method for evaluating mixing protocols. Initially, a computational fluid dynamics (CFD) model may be generated. The CFD model may be capable of determining evaluation criteria based on a selected set of mixing protocol parameters.

After the CFD model is generated, the CFD model may be verified using experimental data. Additionally, sensitivity studies may be conducted to determine the sensitivity of certain modeling parameters such as, for example, mesh resolution, time step, the turbulence model used, the numerical solution method, model of impeller movement, and tracer injection location. Examples of mixing protocol parameters include, but are not limited to, impeller speed, batch size, solution viscosity, solution density, mixing vessel size, mixing vessel geometry, and tracer injection location. Impeller speed may be quantified in terms of revolutions per minute (RPM) or as a percentage of maximum impeller speed. Batch size may refer to the volume of the mixing vessel load, as a percentage of the capacity of the mixing vessel (e.g., a fill volume). Solution viscosity and solution density are parameters specific to a protein of interest and/or a fluid associated with the mixing protocol. During production, solution viscosity and density may be adjusted to achieve desired viscosity and density parameters prior to execution of a mixing protocol.

Referring again to FIG. 1, after the CFD model is verified and the sensitivity of the CFD model is at acceptable levels of variability, a data-driven model may be selected. For example, a relationship between one or more mixing parameters and an evaluation criterion may be regressed. In some embodiments, a relationship may be regressed between blend time and one or more of viscosity, impeller speed, fill volume, impeller diameter, mixer size, or mixer diameter.

Selecting a data-driven model may include identifying mixing parameters that have a significant contribution to variance of the evaluation criterion. After these mixing parameters are identified, a variety of data-driven model types (e.g., types of predictive multivariate models) may be evaluated based on experimental data. A coefficient of determination for each data-drive model type may be evaluated based on the experimental data. The model type with the highest coefficient of determination may be selected.

Once the model type is selected, a predictive multivariate model may be developed based on data derived from CFD analyses. After the predictive multivariate model is developed and trained based on data derived from CFD analyses, it may be used to evaluate mixing protocols in a high-throughput manner.

Data-driven models of the present disclosure may be generated and implemented in a manner that mitigates potential negative effects of implementing the model. For example, the potential risk associated with implementing a data-driven model may be assessed using one or more standardized risk assessment frameworks (e.g., ASME VV40). Models of the present disclosure may undergo sensitivity studies to confirm the impact of various factors (e.g., mixing protocol parameters) on the accuracy of the model. In addition or alternatively, model predications may be validated against experimental data to improve credibility of the model.

In one exemplary evaluation under a standardized risk assessment framework, several inquiries may be made regarding the type and implementation of predictive multivariate models. For example, a question of interest to be investigated by the model may be analyzed, the context of the use of the model may be analyzed, the influence of the model may be analyzed, the consequences of the model may be analyzed, or a combination thereof.

In the context of predictive multivariate model for developing mixing protocols, a question of interest may include whether the proposed operating parameters and mixer configuration ensure homogeneity standards are achieved during mixing operations. The context of the use may include details regarding mechanistic and reduced-order numerical models yielding results to be interpreted in conjunction with experimental data to assess and/or establish mixing process parameters. Model influence may be characterized as low, medium or high. Model influence for the implementation of the predictive multivariate models described herein may be medium, as experimental data is considered to bracket worst-case conditions. Model consequence may be characterized as low, medium, or high. Model consequence for the implementation of the predictive multivariate models described herein may be medium, as in-situ sampling will be conducted to ensure indicators and standards of product quality are met. Model risk may be characterized as low, medium, or high, and model risk may be characterized based on model influence and model consequence. Model risk of the implementation of the predictive multivariate models described herein may be characterized as medium, based on the medium characterizations of model influence and model consequence.

Model predictions may be validated against experimental data, covering a wide range of mixing parameters and vessel sizes to establish model credibility. A subset of models (e.g., a subset of models deemed credible) may undergo sensitivity studies on a wide range of modeling considerations.

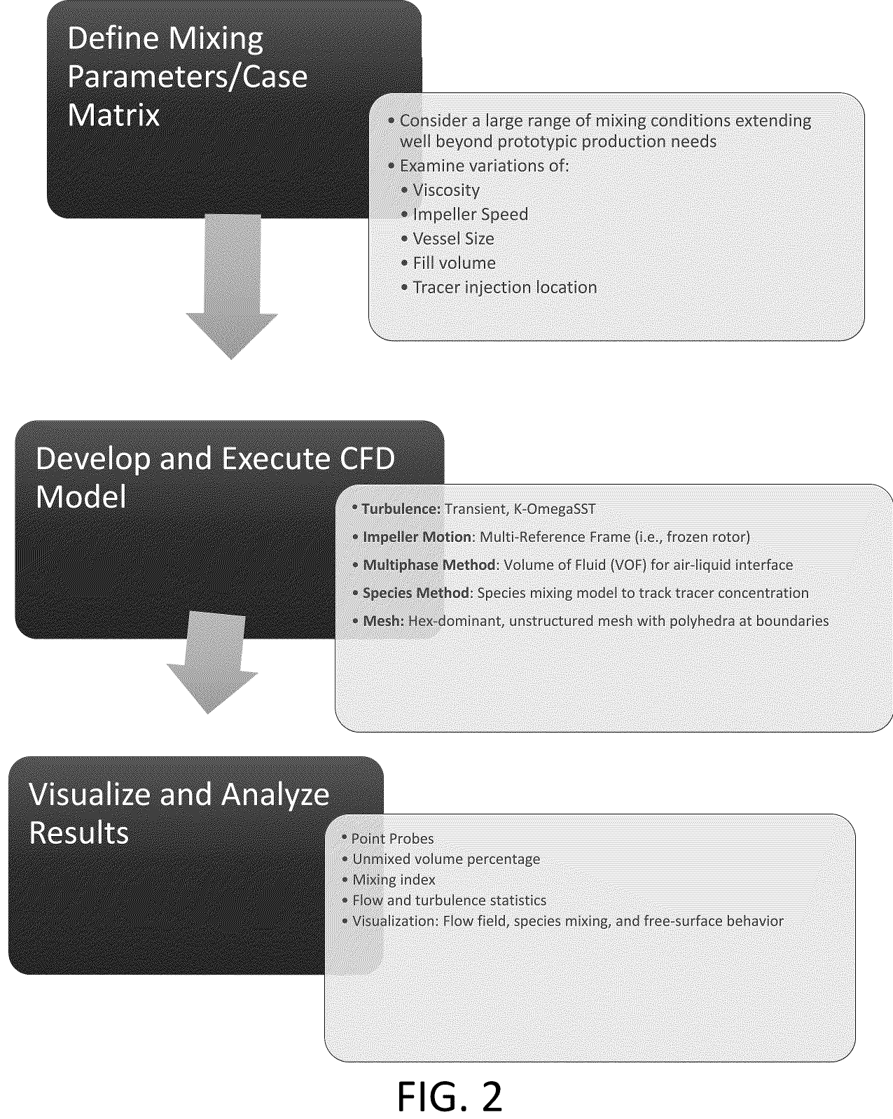

Referring to FIG. 2, a CFD model may be established to evaluate variations in evaluation criteria (e.g., blend time) based on variations of one or mixing protocol parameters. The CFD model may be based on mathematical solutions to fluid flow models, including, but not limited to, laws of conservation, Naiver-Stokes equations, Euler equations, Bernoulli equations, compression wave equations, boundary layer equations, idealized flow, potential flow, duct flow, vortex formation, eddy formation, and turbulence formation. The CFD analysis may be performed by computer system running CFD analysis software, such as, for example, programs including the Star CCM, OpenFoam, Simulia, and Ansys Workbench systems.

Defining mixing parameters and/or a case matrix may include considering a large range of mixing conditions (e.g., a range of mixing conditions extending well beyond prototypic production parameters). Variations in viscosity, impeller speed, vessel size, and fill volume may be examined.

Developing and executing CFD model may include executing CFD model calculations for a set of mixing protocol parameters to generate evaluation criteria. Parameters of executing the CFD model may include modeling turbulence as transient and/or using K-OmegaSST, modeling impeller motion using a multi-reference frame (e.g., frozen rotor), modeling an air-liquid interface may be as a volume of fluid (e.g., a multiphase method), tracking tracer concentration using a species mixing model, modeling movement through the mixing vessel by a hex-dominant unstructured mesh with polyhedra at boundaries, or a combination thereof.

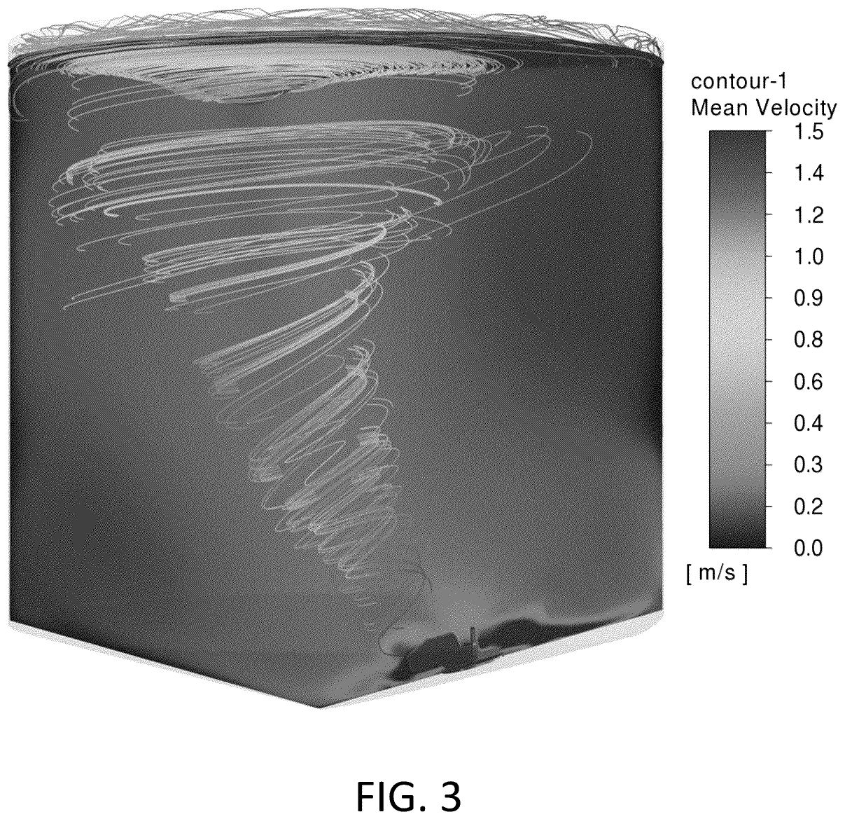

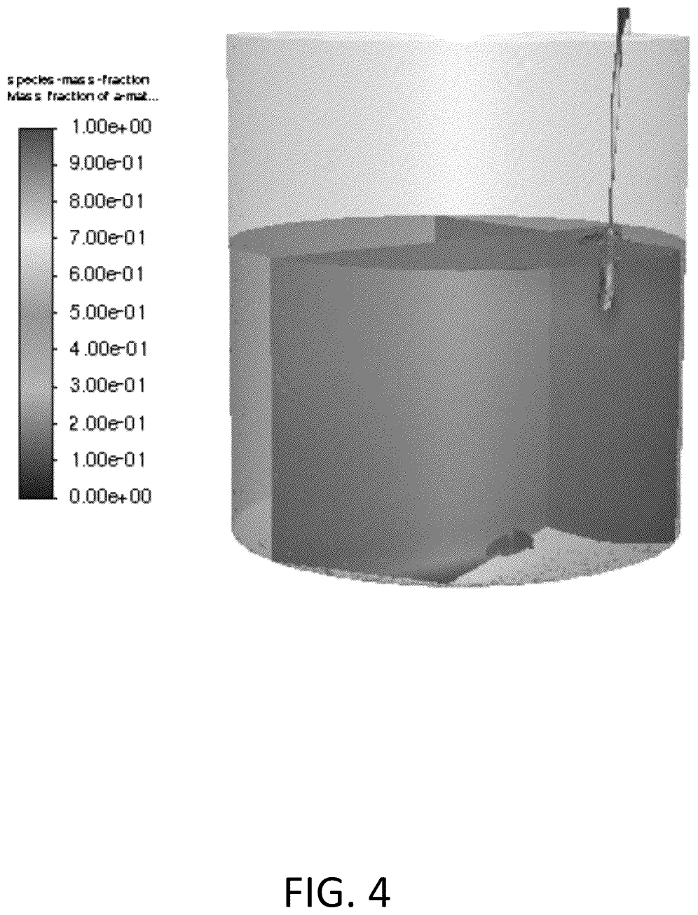

Analyzing results may include using point probes, calculating an unmixed volume percentage, calculating a mixing index, calculating flow and/or turbulence statistics, or a combination thereof. Visualizing results may include generating a flow field plot, a species mixing plot, and/or a free-surface behavior plot. An example of a flow field generated from CFD calculations and including an average velocity is shown in FIG. 3. An example of a species mixing plot is shown in FIG. 4.

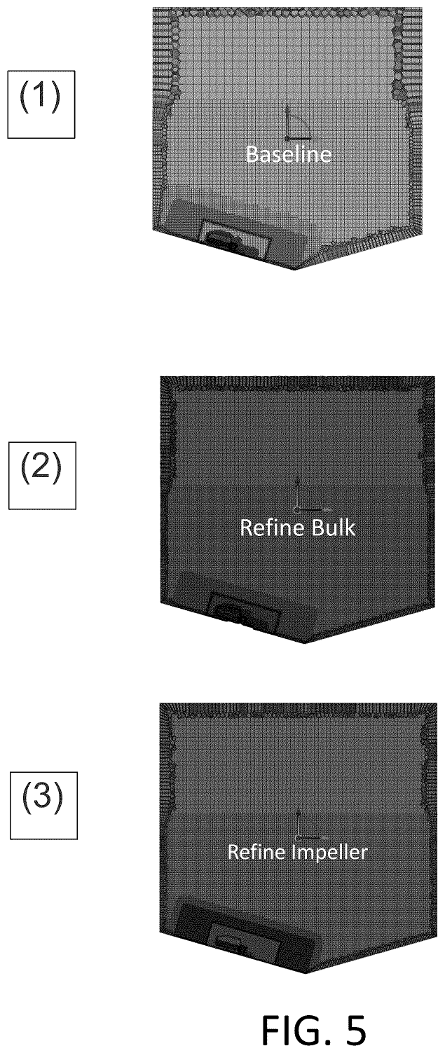

The CFD model may be validated with experimental data for a large range of mixing protocol parameters, including mixing protocol parameters that are outside the range of standard mixing protocol parameters used for production of biopharmaceutical products. Sensitivity studies may be conducted to determine acceptable parameters of the CFD model. Parameters of the CFD model may be refined individually, or in combination. For example, referring to FIG. 5, the mesh resolution of the CFD model may be refined until variance of evaluation criteria is at an acceptable level. In some embodiments, the baseline resolution of the CFD model is refined first, then the mesh resolution of the bulk of the solution is refined, and then the mesh resolution of the region of the model around the impeller is refined. The CFD model may include a finer resolution in the region around the impeller of the mixing vessel, compared to the average mesh resolution of the CFD model.

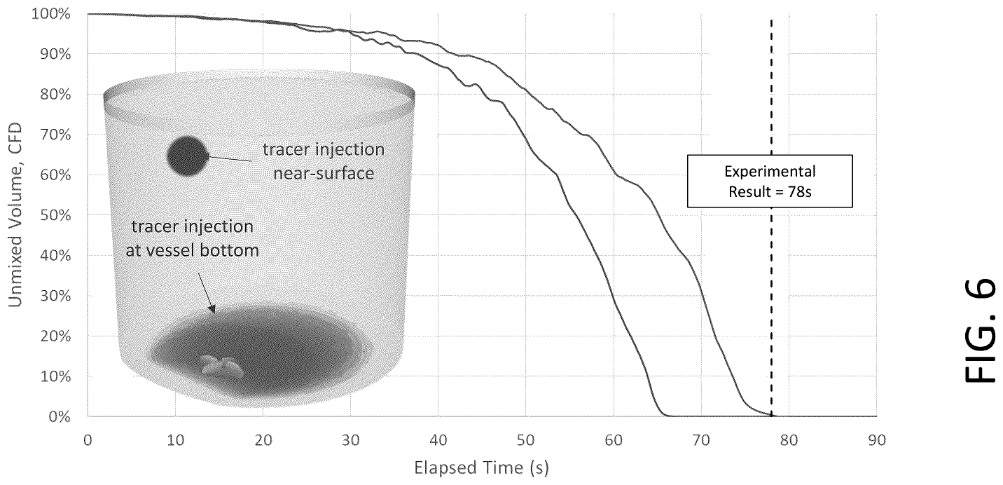

In addition or alternatively, sensitivity studies may be conducted to confirm that variance of evaluation criteria due to the time step, turbulence model, numerical solution method, impeller modeling (e.g., static, dynamic, multi-reference frame), and/or tracer injection location used in the CFD model are acceptable. As one example, a plot of unmixed volume versus time elapsed in shown in FIG. 6. The top line represents unmixed volume as calculated by a CFD model, based on the assumption that the tracer is injected to a bottom of the mixing vessel. The bottom line represents unmixed volume as calculated by a CFD model, based on the assumption that the tracer is injected near the surface of the mixing vessel. The data shown in this plot indicate inclusion of tracer injection location into the CFD model is important when considering experimental validation of the CFD model.

In addition or alternatively to tracer injection location, other parameters that may be refined during sensitivity studies may include a time step, a turbulence model used (e.g., transient and/or K-OmegaSST), a numerical solution method, a propeller modeling technique (e.g., frozen rotor or dynamic mesh), or a combination thereof.

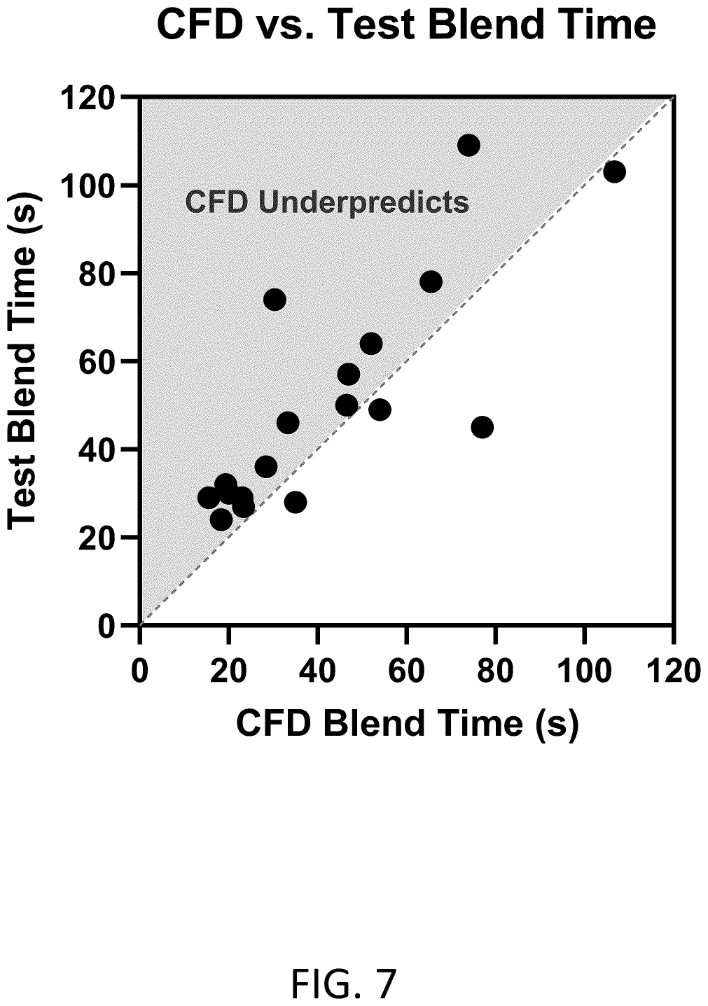

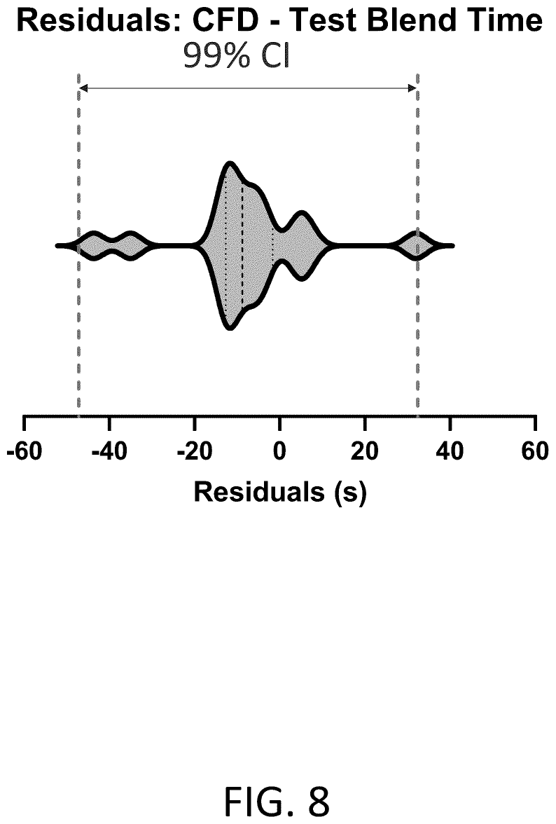

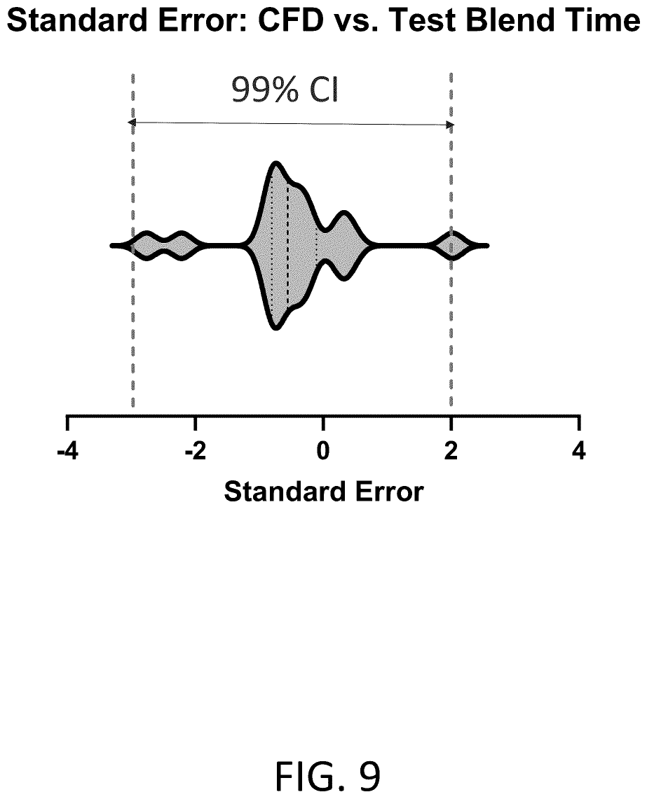

Referring to FIG. 7, an example of verifying a CFD model using experimental data is shown. The CFD model was used to evaluate blend time for a range of mixing protocol parameters, including multiple vessel sizes, fill volumes, fluid viscosities, and impeller speeds. Exemplary values for the mixing protocol parameters are shown in Table 1. FIG. 7 shows experimentally determined blend times plotted against blend times determined by the CFD model. The plot also includes a line of best fit. The relative error of the blend times determined by CFD are shown in FIGS. 8 (residuals) and 9 (standard error).

TABLE 1

| Mixing Protocol Parameter | Exemplary Parameter Values |
|---|---|
| Mixing Vessel Size | 10-1000 L (e.g., 10, 50, 100, 500, and/or |
| | 1000 L) |
| Batch Size | 10-100% of the mixing vessel size (e.g., |
| | 10%, 50%, and/or 100% fill) |
| Fluid Viscosity | 1-56 cP (e.g., 1 cP, 10 cP, 13 cP, 20 cP, |
| | 30 cP, 45 cP, 53 cP, and/or 56 cP) |
| Impeller Speeds | 70-1000 RPM (e.g., 70, 120, 250, 350, 500, |
| | and/or 1000 RPM) |

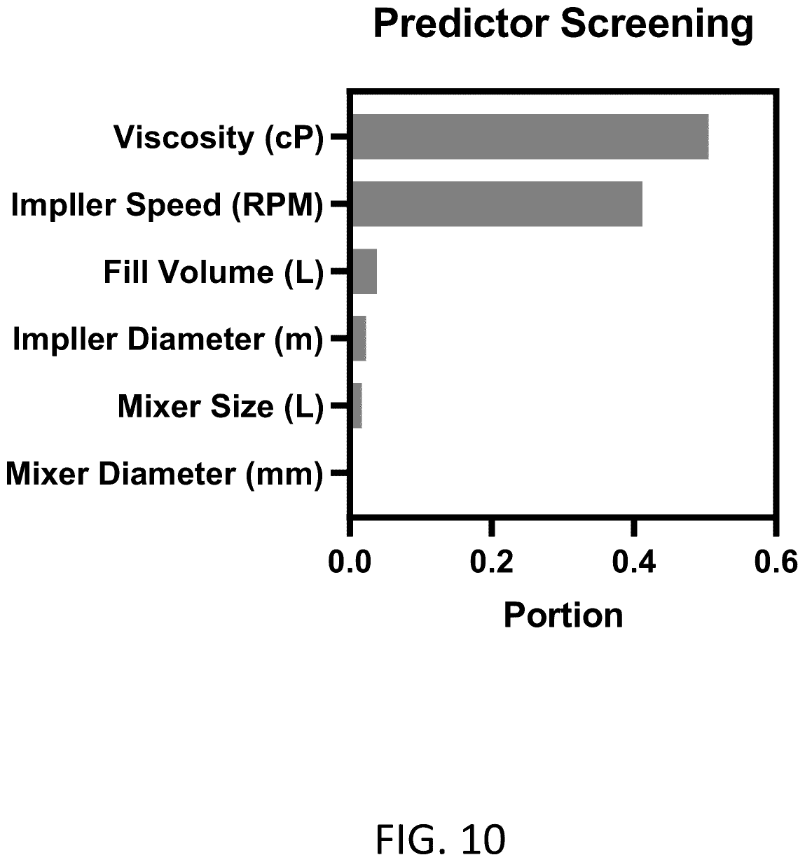

Referring to FIG. 10, one or more feature selection algorithms may be applied to determine mixing protocol parameters that have the greatest impact on one or more evaluation criteria. For example, a feature selection algorithm (e.g., Random Forest) may be applied to experimentally determined data and/or data generated using a CFD model. The plot on the of FIG. 10 shows an exemplary predictor screening using Random Forest of six mixing protocol parameters and indicates that viscosity, impeller speed, fill volume, and impeller diameter account for 90% of the observed blend time variance.

Multiple predictive multivariate models of different types may be generated to calculate one or more evaluation criteria as a function of one or more mixing protocol parameters (e.g., mixing protocol parameters with the greatest impact on the evaluation criteria). The coefficient of determination for each type of multivariate model may be determined. The type of multivariate model that exhibits the greatest coefficient of determination may be selected for fine tuning, training, and/or evaluating mixing protocols.

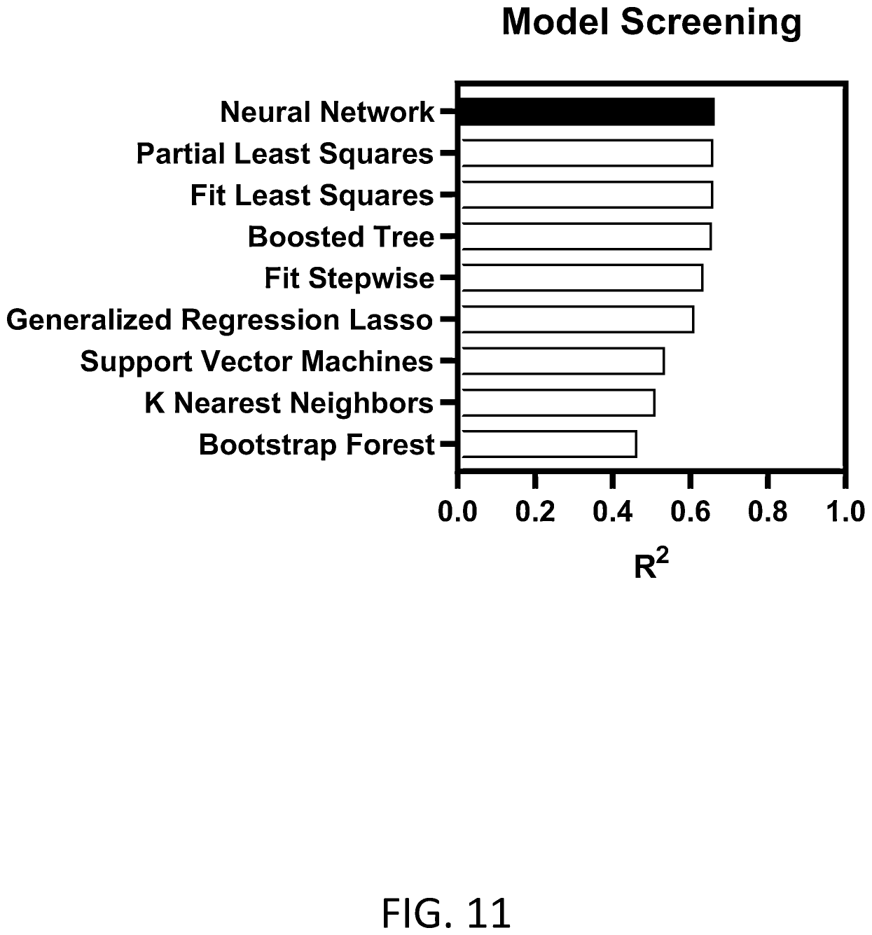

For example, referring to FIG. 11, nine different multivariate models were developed to calculate blend time as a function of viscosity, impeller speed, fill volume, and impeller diameter. The artificial neural network had larger coefficient of determination, compared to the other types of multivariate predictive models. In some embodiments, the artificial neural network.

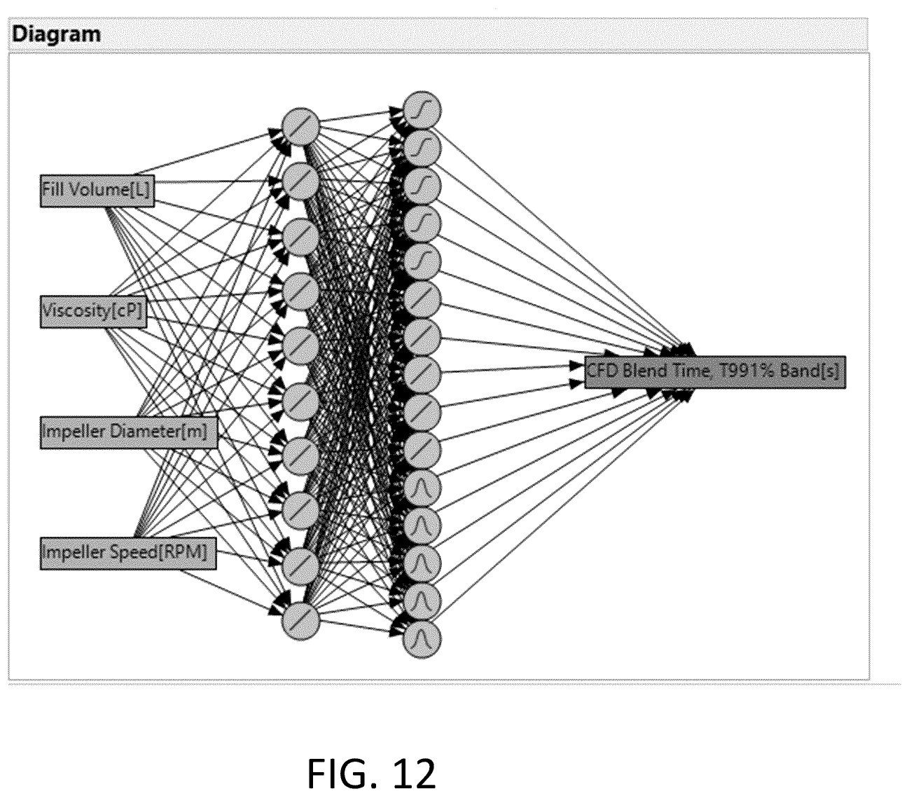

Referring to FIG. 12, a diagram of an exemplary artificial neural network relating blend time as a function of fill volume, viscosity, impeller diameter, and impeller speed is shown. The exemplary artificial network shown in FIG. 12 includes four mixing protocol parameters, a first level comprising ten nodes, and a second level including fifteen nodes, however, this is one example. Artificial neural networks of the present disclosure may include any number of mixing protocol parameters, levels and/or nodes. In some embodiments, sensitivity studies may be conducted to determine the most efficient number of mixing protocol parameters, levels and/or nodes.

The nodes of the first level of the exemplary artificial neural network shown FIG. 12 are linear activation nodes that include linear relationships between one or more mixing protocol parameters. The nodes of the second level of the network includes linear, Gaussian, and tangent hyperbolic relations of one or more linear combinations of one or more mixing protocol parameters. A node of the artificial neural network may include a dynamic and/or static relative weight, compared to other notes of the network.

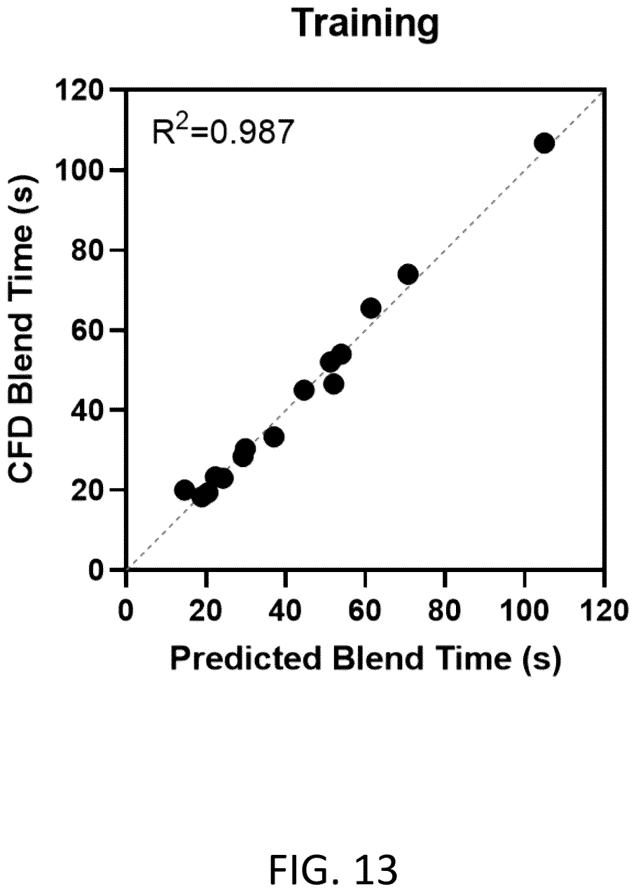

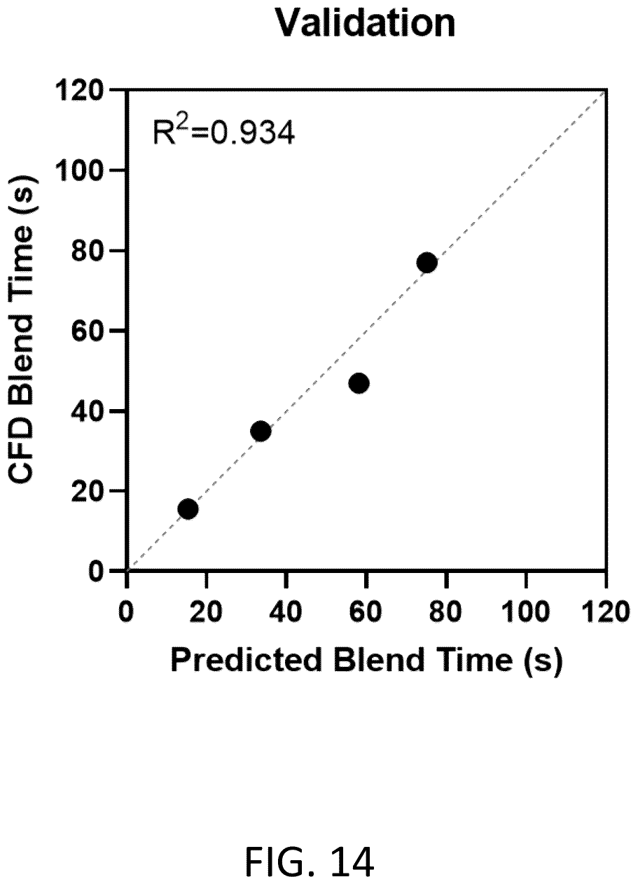

Developing a predictive multivariate model (e.g., an artificial neural network) may include dividing a data set (e.g., a set of data determined using a CFD model) into a training set and a validation set. In some embodiments, the training set includes using a percentage (e.g., 80%) of the data points and the validation set includes the remaining percentage (e.g., 20%) of the data points. Referring to FIG. 13, a plot of the training set for the artificial neural network described herein is shown. Referring to FIG. 14, a plot of the validation set for the artificial neural network described herein is shown. While the multivariate model performs better on the training set, than the validation set, the coefficient of determination for the validation set is still greater than 0.9.

After the multivariate model (e.g., artificial neural network) is trained and validated, it can be used to evaluate mixing protocols in a high-throughput manner. For example, the model may be used to plot a relationship between mixing protocol parameters and evaluation criteria. Referring to the exemplary artificial neural network described above, the relationship between blend time and viscosity, impeller speed, fill volume, and impeller diameter can be plotted to identify optimal mixing protocols for further evaluation. As the relationship between these variable is a 5-dimensional relationship, two mixing protocol parameters may be held constant to visualize the effect of the two other mixing protocol parameters on the blend time.

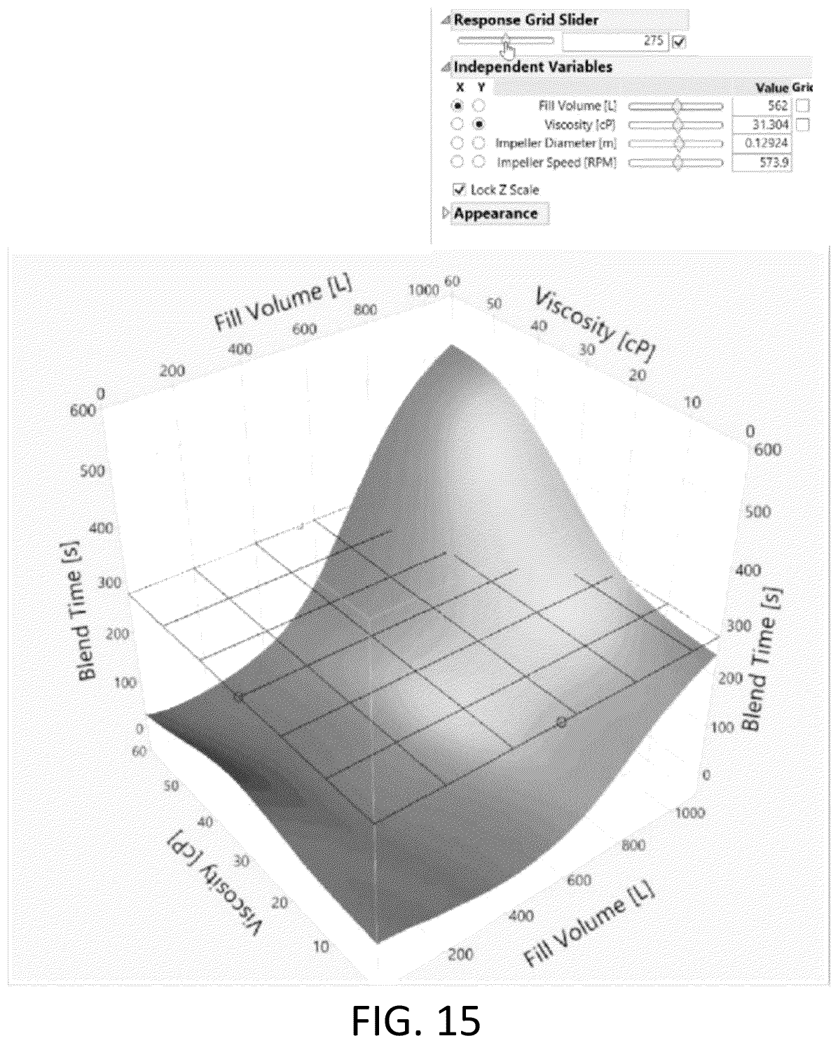

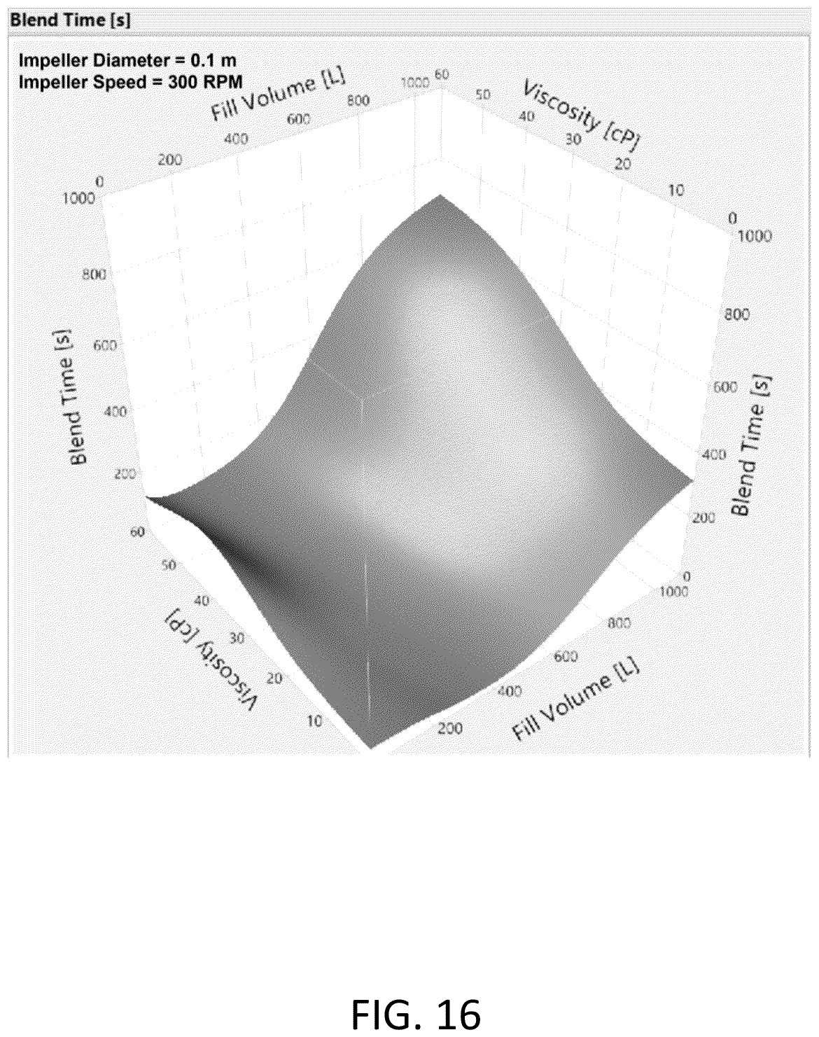

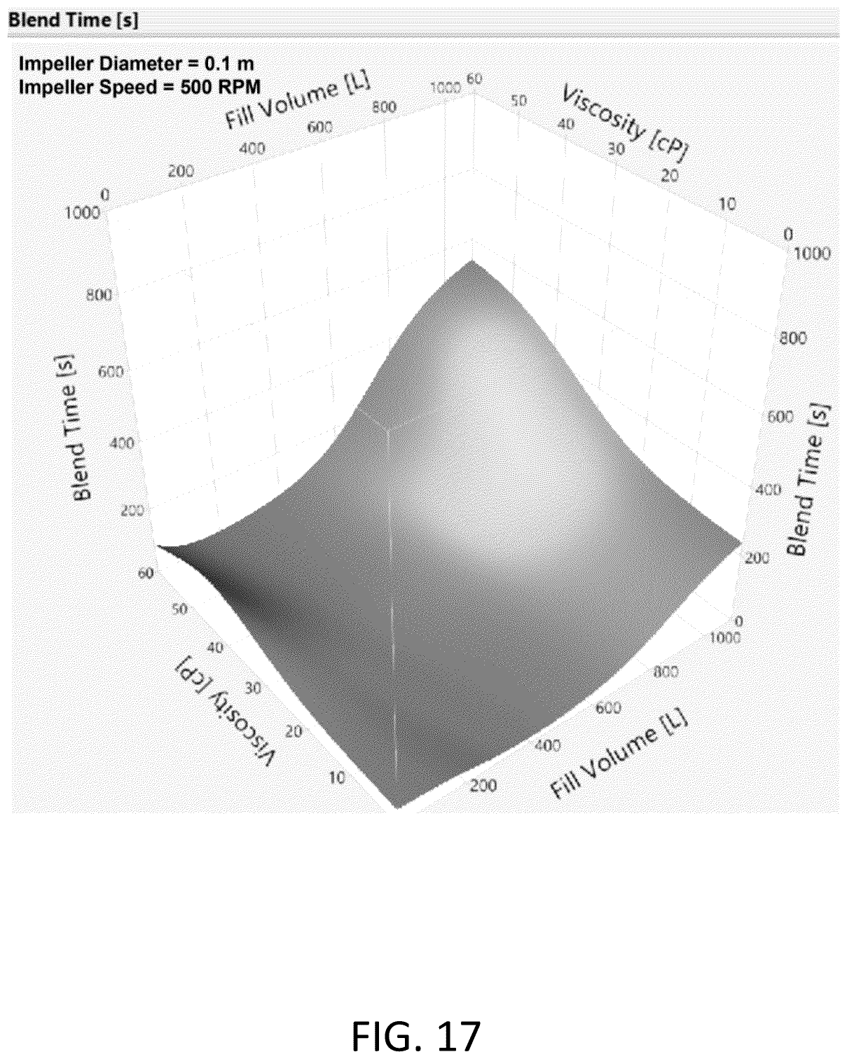

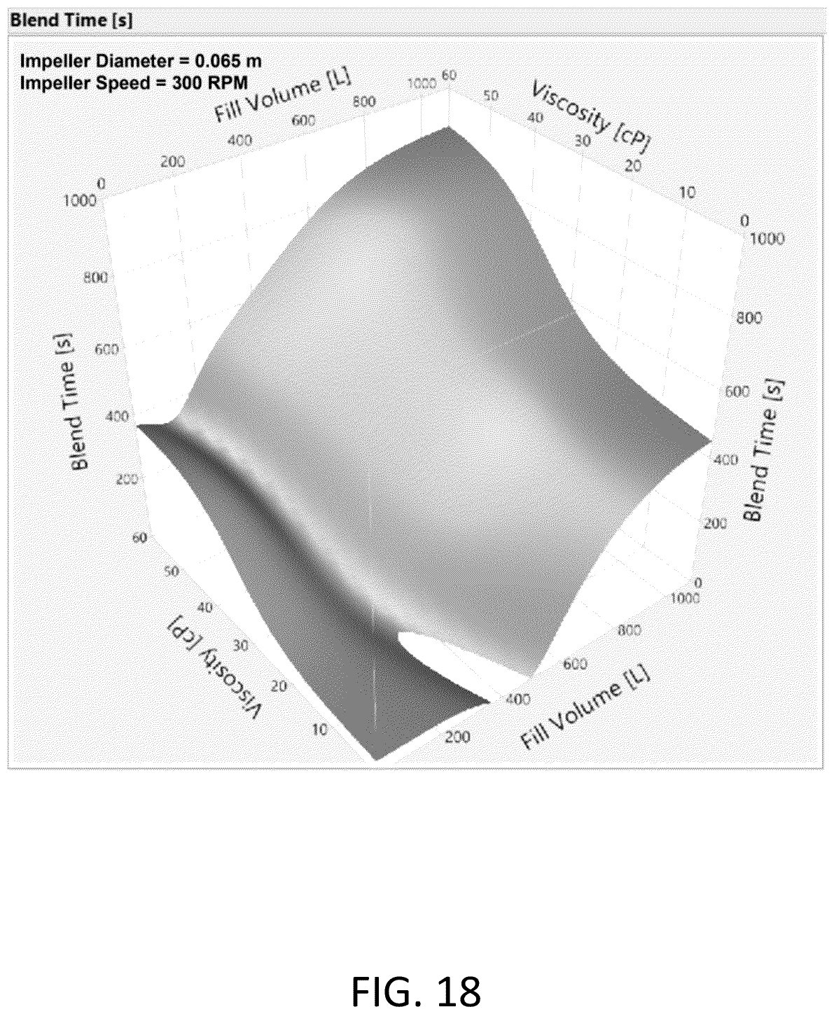

Referring to FIG. 15, an image of a plotted relationship between blend time and viscosity, impeller speed, fill volume, and impeller diameter is shown. As shown in the exemplary independent variable slider shown in FIG. 15, impeller diameter and impeller speed are held constant to visualize the effect of viscosity and fill volume on blend time, at the selected impeller diameter and speed. Referring to FIGS. 16, 17, and 18, as impeller diameter and impeller speed are varied, the plot also changes to reflect the effect of varied impeller diameter and impeller speed on the relationship between viscosity, fill volume, and blend time.

In each of the plots shown in FIGS. 15-18, impeller diameter and impeller speed are held constant to show variations in blend time as a function of viscosity and fill volume. One of the benefits of a multivariate model (e.g., the exemplary artificial neural network) is the ability to visualize the impact of more than two variables (e.g., mixing protocol parameters). Using the same model, two other mixing protocol parameters may be held constant (e.g., viscosity and impeller diameter) two visualize variations in blend time as a function of other mixing protocol parameters (e.g., fill volume and impeller speed).

Advantageously, the high-throughput manner of evaluating mixing protocols may result in significant time savings in identifying mixing protocols suitable for use in the production of biopharmaceutical products. Incorporating multivariate models into mixing protocol development may provide numerous benefits. For example, conventional experimentally driven processes of developing mixing protocols are labor intensive and incur high material costs. The iterative nature of experimentally driven processes increases the associated labor and material costs.

Incorporation of CFD-alone into conventional processes of developing mixing protocols can also be problematic. CFD is computationally intensive and can require large amounts of resources to achieve a limited number of data points. Additionally, CFD-based processes must be validated for each unique set of conditions. Due to the time associated with CFD calculations and validation requirements, CFD can be impractical for the development of robust and flexible mixing protocols.

In the conventional development of a mixing protocol, physiochemical properties of the protein of interest and the media containing the protein of interest are considered as potential mixing protocols are generated. The potential mixing protocols are tested via surrogate mixing studies to map operating ranges and collect blend time data. Based on the blend time data collected from various points of the operating ranges, one or more candidate mixing protocols may be determined.

This conventional development flow of a mixing protocol is limited because surrogate mixing studies must be performed to evaluate mixing protocols that may eventually result in unfavorable product quality data. The requirement of the conventional development flow to run multiple experiments in order to determine whether a potential mixing protocol should be investigated results in a time and labor intensive development of mixing protocols. Further, events related to an implemented mixing protocol that affect the quality of the resulting biopharmaceutical product, such as air-liquid interfacial stress, air entrainment, and risk of visible or sub-visible particle formation are not addressed in the conventional development flow.

The surrogate mixing studies, shear stress, and overmixing investigations associated with conventional mixing protocol development do not quantify air-liquid interfacial stress, air entrainment, and risk of visible or sub-visible particle formation. Therefore, these metrics are conventionally assessed with full-scale investigations using actual biopharmaceutical product. Full-scale investigations using product are expensive and time consuming. The cost and time constraints of full-scale investigations reduce repeatability and increase the difficulty of collecting enough samples to reduce sampling variability. Further, probes associated with the full-scale investigations may impact the flow associated with the mixing protocol, and provide inaccurate data.

Further, validation of a mixing protocol is dependent on a specific biopharmaceutical product and the parameters of the mixing protocol. Any changes to the mixing protocol or structure of the biopharmaceutical product requires additional mixing studies and full-scale investigations to validate the modified mixing protocol. Therefore, there exists a need for a methods of developing robust predictive models capable of evaluating and validating mixing protocols over a wide range of mixing protocol parameters.

The methods described herein enable to the generating of mixing protocols in a more cost and time efficient manner, compared to conventional methods. For example, conventional experimentally-driven processes are labor and materials intensive. Additionally, conventional experimentally-driven processes require multiple iterative loops, increasing labor and material costs. Conventional CFD-driven processes are computationally-intensive and present validations challenges. The methods described herein, including generation of a multivariate model (e.g., a neural network) allow for efficient evaluation of mixing protocols at multiple scales.

Processes of developing mixing protocols including data-driven predictive multivariate models, such as those described in the present disclosure, address the shortcomings of conventional methods of developing mixing protocols.

The present disclosure is further described by the following non-limiting items.
Item 1. A method of evaluating a mixing protocol, the method comprising:
identifying a domain of mixing protocol parameters for a multivariate model;
identifying an evaluation criterion for the multivariate model;
using predictor screening to determine a set of mixing protocol parameters from the domain of mixing protocol parameters, wherein the set of mixing protocol parameters account for a threshold observed variance in the evaluation criterion;
generating the multivariate model, wherein the multivariate model relates the set of mixing protocol parameters to the evaluation criterion;
using the multivariate model, generating an estimated value of the evaluation criterion for the mixing protocol.
Item 2. The method of item 1, wherein the predictor screening is based on experimental data or data derived from a computational fluid dynamics (CFD) model.
Item 3. The method of item 2, wherein the predictor screening is based on experimental data and data derived from the CFD model, and the method further comprises, prior to generating the multivariate model, verifying the CFD model using experimental data.
Item 4. The method of item 1, wherein the threshold observed variance in the evaluation criterion is approximately 90% of the observed variance in the evaluation criterion.
Item 5. The method of item 1, wherein the set of mixing protocol parameters includes at least three mixing protocol parameters.
Item 6. The method of item 1, wherein the set of mixing protocol parameters includes five or less mixing protocol parameters.
Item 7. The method of item 1, wherein the set of mixing protocol parameters includes viscosity, impeller speed, fill volume, and impeller diameter.
Item 8. The method of item 1, wherein the evaluation criterion is blend time.
Item 9. The method of item 1, wherein the predictor screening includes Random Forest.
Item 10. The method of item 1, further comprising generating a plot representing the multivariate model.
Item 11. The method of item 1, wherein the multivariate model is an artificial neural network.
Item 12. The method of item 11, wherein the artificial neural network is trained on data including experimental data, data derived from a computational fluid dynamics (CFD) model, or both.
Item 13. The method of item 11, wherein the artificial neural network includes a first level of nodes and a second level of nodes.
Item 14. The method of item 13, wherein the first level of nodes includes a linear activation node comprising linear relationships between one or more mixing protocol parameters of the set of mixing protocol parameters.
Item 15. The method of item 13, wherein the second level of nodes includes linear, Gaussian, and tangent hyperbolic relations of one or more linear combinations of one or more mixing protocol parameters of the set of mixing protocol parameters.
Item 16. A method of evaluating a mixing protocol, the method comprising:
verifying a computational fluid dynamics (CFD) model using experimental data;
using predictor screening to determine a set of mixing protocol parameters from a domain of mixing protocol parameters;
generating an artificial neural network, wherein training data for the artificial neural network includes data generated from the CFD model, and wherein the artificial neural network relates the set of mixing protocol parameters to an evaluation criterion and includes:
   a first level of nodes including a linear activation node comprising linear relationships between one or more mixing protocol parameters of the set of mixing protocol parameters; and
   a second level of nodes including linear, Gaussian, and/or tangent hyperbolic relations of one or more linear combinations of one or more mixing protocol parameters of the set of mixing protocol parameters; and
using the artificial neural network, generating an estimated value of the evaluation criterion for the mixing protocol.
Item 17. The method of item 16, wherein the set of mixing protocol parameters includes at least three mixing protocol parameters.
Item 18. The method of item 16, wherein the set of mixing protocol parameters includes five or less mixing protocol parameters.
Item 19. The method of item 16, wherein the set of mixing protocol parameters includes viscosity, impeller speed, fill volume, and impeller diameter.
Item 20. The method of item 16, wherein the evaluation criterion is blend time.
Item 21. The method of item 16, wherein the mixing protocol includes a protocol value for each mixing protocol parameter of the set of mixing protocol parameters, and wherein generating the estimated value of the evaluation criterion for the mixing protocol includes generating the estimated value based on the protocol values of the mixing protocol.

Those skilled in the art will appreciate that the conception upon which this disclosure is based may readily be used as a basis for designing other methods and systems for carrying out the several purposes of the present disclosure. Accordingly, the claims are not to be considered as limited by the foregoing description.

What is claimed is:

1. A method of evaluating a mixing protocol, the method comprising:
identifying a domain of mixing protocol parameters for a multivariate model;
identifying an evaluation criterion for the multivariate model;
using predictor screening to determine a set of mixing protocol parameters from the domain of mixing protocol parameters, wherein the set of mixing protocol parameters account for a threshold observed variance in the evaluation criterion;
generating the multivariate model, wherein the multivariate model relates the set of mixing protocol parameters to the evaluation criterion; and
using the multivariate model, generating an estimated value of the evaluation criterion for the mixing protocol.

2. The method of claim 1, wherein the predictor screening is based on experimental data or data derived from a computational fluid dynamics (CFD) model.

3. The method of claim 2, wherein the predictor screening is based on experimental data and data derived from the CFD model, and the method further comprises, prior to generating the multivariate model, verifying the CFD model using experimental data.

4. The method of claim 1, wherein the threshold observed variance in the evaluation criterion is approximately 90% of the observed variance in the evaluation criterion.

5. The method of claim 1, wherein the set of mixing protocol parameters includes at least three mixing protocol parameters.

6. The method of claim 1, wherein the set of mixing protocol parameters includes five or less mixing protocol parameters.

7. The method of claim 1, wherein the set of mixing protocol parameters includes viscosity, impeller speed, fill volume, and impeller diameter.

8. The method of claim 1, wherein the evaluation criterion is blend time.

9. The method of claim 1, wherein the predictor screening includes Random Forest.

10. The method of claim 1, further comprising generating a plot representing the multivariate model.

11. The method of claim 1, wherein the multivariate model is an artificial neural network.

12. The method of claim 11, wherein the artificial neural network is trained on data including experimental data, data derived from a computational fluid dynamics (CFD) model, or both.

13. The method of claim 11, wherein the artificial neural network includes a first level of nodes and a second level of nodes.

14. The method of claim 13, wherein the first level of nodes includes a linear activation node comprising linear relationships between one or more mixing protocol parameters of the set of mixing protocol parameters.

15. The method of claim 13, wherein the second level of nodes includes linear, Gaussian, and tangent hyperbolic relations of one or more linear combinations of one or more mixing protocol parameters of the set of mixing protocol parameters.

16. A method of evaluating a mixing protocol, the method comprising:
verifying a computational fluid dynamics (CFD) model using experimental data;
using predictor screening to determine a set of mixing protocol parameters from a domain of mixing protocol parameters;
generating an artificial neural network, wherein training data for the artificial neural network includes data generated from the CFD model, and wherein the artificial neural network relates the set of mixing protocol parameters to an evaluation criterion and includes:
a first level of nodes including a linear activation node comprising linear relationships between one or more mixing protocol parameters of the set of mixing protocol parameters; and
a second level of nodes including linear, Gaussian, and/or tangent hyperbolic relations of one or more linear combinations of one or more mixing protocol parameters of the set of mixing protocol parameters; and
using the artificial neural network, generating an estimated value of the evaluation criterion for the mixing protocol.

17. The method of claim 16, wherein the set of mixing protocol parameters includes at least three mixing protocol parameters.

18. The method of claim 16, wherein the set of mixing protocol parameters includes five or less mixing protocol parameters.

19. The method of claim 16, wherein the set of mixing protocol parameters includes viscosity, impeller speed, fill volume, and impeller diameter.

20. The method of claim 16, wherein the evaluation criterion is blend time.

21. The method of claim 16, wherein the mixing protocol includes a protocol value for each mixing protocol parameter of the set of mixing protocol parameters, and wherein generating the estimated value of the evaluation criterion for the mixing protocol includes generating the estimated value based on the protocol values of the mixing protocol.
